(19) United States
(12) Patent Application Publication
(10) Pub. No.: US 2014/0181603 A1
(43) Pub. Date: Jun. 26, 2014

(54) METHOD AND APPARATUS FOR TUNING SCAN CAPTURE PHASE ACTIVITY FACTOR

(71) Applicants: Iwan R. Grau, Gilbert, AZ (US); Victor G. Delagarza, Gilbert, AZ (US); Jeff J. McCoskey, Phoenix, AZ (US); Mithilesh K. Das, Chandler, AZ (US); Lance C. Cheney, El Dorado Hills, CA (US); Jackie M. Cooper, Chandler, AZ (US)

(72) Inventors: Iwan R. Grau, Gilbert, AZ (US); Victor G. Delagarza, Gilbert, AZ (US); Jeff J. McCoskey, Phoenix, AZ (US); Mithilesh K. Das, Chandler, AZ (US); Lance C. Cheney, El Dorado Hills, CA (US); Jackie M. Cooper, Chandler, AZ (US)

(21) Appl. No.: 13/725,708

(22) Filed: Dec. 21, 2012

(51) Int. Cl. G01R 31/3177

(52) U.S. Cl. CPC G01R 31/3177
USPC 714/727; 714/726

(57) ABSTRACT

A method and apparatus for tuning the activity factor of a scan capture phase is described. In one example an activity factor is determined for a die to be tested. The die may be isolated or part of a wafer. A structural scan test is modified to run with an activity factor based on the determined activity factor. The modified structural scan test is run and the die is characterized based on the test.

### FIELD

The present disclosure relates to the field of testing an integrated circuit die and, in particular, to tuning operation of the die while under structural scan test.

### BACKGROUND

Among the many tests to which integrated circuits (IC) are exposed, from fabrication to final customer end use, are tests that attempt to emulate normal operations using various means. One of the most efficient of these tests methods is a structural test type known as scan or Algorithmic/Automated Test Pattern Generation (ATPG). These tests are used to test for defects and to characterize an IC's operating frequency and to determine whether it can sustain normal operation long term. ATPG is designed to enhance the efficacy of the characterization of the IC's operating frequency.

On the other hand, functional tests that apply functional vectors to an IC have significant research and development costs and significant production costs which include the initial development of the IC to include a provision for the test. In addition to designing and implementing the functional design for test facility in the silicon, expensive medium and high speed testers, with large memories, must be acquired and applied. Architecturally skilled IC design engineers are required to write the tests, to grade faults, and to close coverage holes in the test suite. In addition, architecturally skilled production engineers are required to bring up and debug functional manufacturing tests. These requirements extend the time required to design and to manufacture new silicon. Scan testing addresses many of these shortcomings but have traditionally not been as effective as functional based tests at characterizing the operating speed of units.

### BRIEF DESCRIPTION OF THE DRAWINGS

Embodiments of the invention are illustrated by way of example, and not by way of limitation, in the figures of the accompanying drawings in which like reference numerals refer to similar elements.

FIG. 1 is a diagram of a graph of power supply voltage under different load conditions.

FIG. 2 is a diagram of a two scan chains through an IC showing logic circuit activity under normal functional operation.

FIG. 3 is a diagram of a two scan chains through an IC showing logic circuit activity under structural scan.

FIG. 4 is a diagram of a two scan chains through an IC showing logic circuit activity under a tuned structural scan tuned to resemble the activity factor of normal functional operation according to an embodiment of the invention.

FIG. 5 is a diagram of a two scan chains through an IC showing logic circuit activity under a tuned structural scan tuned to resemble the activity factor of normal functional operation using gated clock regions according to an embodiment of the invention.

FIG. 6 is a diagram of a two scan chains through an IC showing logic circuit activity under a tuned structural scan tuned to resemble the activity factor of normal functional operation using gated clocks with hold or rotate control according to an embodiment of the invention.

FIG. 7 is a diagram of an IC with a scan chain affecting boundary and inner logic and clock elements according to an embodiment of the invention.

FIG. 8 is a diagram of test equipment configuration for operating scan chains according to an embodiment of the invention.

FIG. 9A is a process flow diagram of tuning a structural scan according to an embodiment of the invention.

FIG. 9B is a process flow diagram of applying a tuned structural scan according to an embodiment of the invention.

FIG. 9C is process flow diagram using and modifying a structural scan for test according to an embodiment of the invention.

FIG. 10 is block diagram of a computer system suitable for implementing processes of the present disclosure according to an embodiment of the invention.

### DETAILED DESCRIPTION

Integrated circuit (IC) test is performed in part using scan tests, also called in-circuit tests, structural tests, ATPG tests, and scan chain tests. For scan testing the IC includes one or more chains of connected scan flops or cells in a scan path. These flip-flops for scans are typically some of the same circuitry that is used for normal operation of the IC but fitted with additional connections for scan chain tests. In other implementations, the scan chains are formed by chaining sequential elements that shadow functional flops. Each path generally has one scan shift input and one scan shift output.

During a test, test vectors are scanned by being shifted into the inputs of the scan chain(s) one bit per chain for each shift cycle. This is referred to as the shift phase. The bits propagate through the chain(s) one scan flop per chain at a time until the entire test vector has been input. At this point, the chain controls are reconfigured to exercise the circuit as it normally functions for customer operation. This is the beginning of the capture phase. The capture phase consists of creating and releasing a controlled number of clocks to allow the circuit under test to operate as it normally would. Once the capture phase is over the scan chains are reconfigured to shift out the captured content. This is usually used to simultaneously shift in new vectors. As the scanned data propagates through the chain it will eventually appear at the end of the chain(s), referred to as the scan chain output(s), one bit, per chain, at a time and can be compared to the expected output to determine pass or fail status for the test conditions applied during the capture cycle. These conditions include temperature, voltage, frequency and the process characteristics of that unit.

Typically, the shift portion of the test is applied at a reduced speed to maintain data integrity due to timing limitations of the shift paths and power droop imposed limitations. The capture phase is run various ways. One way is at reduced speeds in what is commonly referred to in the industry as stuck-at scan. This capture phase can also be run in what is commonly referred to as at-speed or transition scan mode where the capture clock edges are released at high speeds. The tunable capture phase method described herein can operate under all these modes of capture phase operation but greater benefits may be realized by targeting the at-speed method. This is because the at-speed method provides a simple means to target the activity factor on each capture phase cycle thus mitigating the supply voltage droop.

The purpose of the scan test is typically to verify that the logic components of the IC are defect free, Even though scan tests exercise functional logic paths, they do not attempt to emulate actual functional transactions. One key difference is that scan simultaneously excites, on average, more paths than would a functional test. Because of the many functional paths being simultaneously activated as compared to the typical counts of paths being activated under normal functional usage, the demands on the power delivery solution can be greater under scan execution. As a result, the resulting voltage droops are also greater. The larger voltage droop results in lower relative speed performance of the functional circuit during the capture phase, than would normally occur in true functional operation. This has the effect of artificially indicating that the IC is only capable of operating at lower speeds. Another area where the emulation capability is different between scan capture execution and functional execution is that scan typically executes only a few cycles. This short duration of the capture phase, relative to continuous functional operation, also adds to scan's inability to accurately predict the speed at which an IC is capable of running normal functional operations.

Structural scan testing has the advantages of being easy to implement and includes powerful debug capabilities. Transferring the fault coverage and speed binning requirements to an at-speed structural test would allow expensive functional testing to be avoided. Structural scan test is significantly easier and faster to bring up. However structural scan does not run at normal speed or temperature and due to the very heavy activity factor induced by the scan vectors, structural scan does not emulate normal operation.

Efforts to reduce the supply droops of structural scan have been made and mainly take one or both of two forms: a) reducing the shift phase power for scan testing; and b) reducing the capture phase activity factors for the test vectors. Reducing the shift phase power does not mitigate the Vcc droop that occurs to the power supplied to the logic under test during the capture phase of scan test. Embodiments of the present invention are compatible with this shift phase power mitigation strategy. The vector activity factor method also works well with embodiments of the present invention. These other efforts do not provide the DUT's scan controller with any means to directly and actively and uniformly control power and instead are based on reusing the pre-existing, sometimes limited and non-uniform, functional power control mechanisms of the functional logic under test. Although usually automated by the tools used to create scan vectors, these methods typically result in a significant growth in test vector count and/or loss of coverage when forced to meet the low activity factor target often required for correlation to functional vectors.

In addition there have been efforts, to pre-compensate the power supply Vcc, but these have been limited in their ability to match normal functional operating voltage droops consistently across the process, voltage, and temperature variations seen in conventional operational test environments and the logic circuits being tested. All of these efforts struggle in maintaining a consistent droop throughout the capture phase.

Embodiments of the present invention allow the capture phase activity factor in a structural scan test to be accurately controlled and tuned to emulate normal operation. The control and tuning is not affected by the nature of the particular IC and can be used to cause the Vcc droop to tightly match that obtained when running functional test vectors on the IC under test. According to embodiments described herein, standard structural scan vectors can be transformed into tunable low capture phase activity factor vectors. Although not limited to this purpose, this is especially useful in using embodiments of this invention to characterize the target activity factor that best emulates normal functional execution. Embodiments of the invention can also be used to enable scan tooling to generate vectors to meet a specific activity factor, thus making the vectors more efficient at attaining target coverage requirements.

The structural scan test is an efficient scan methodology that is generic in implementation and debug requirements across products, As a result, the need for extensive architecturally experienced implementation and debug engineers is reduced for each IC program.

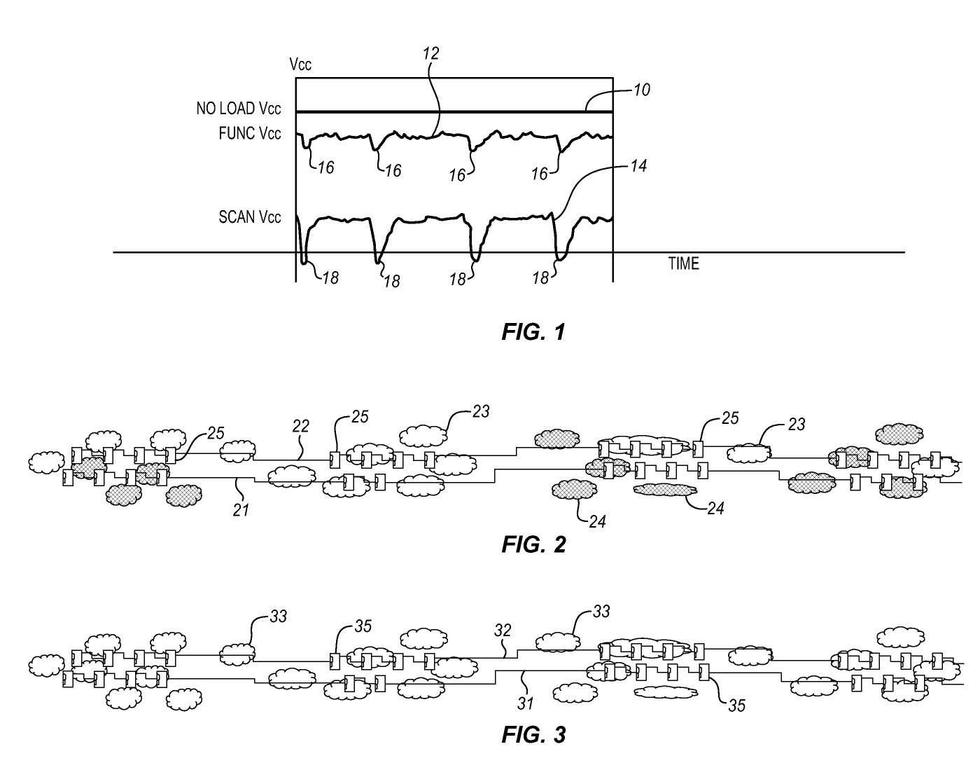

FIG. 1 shows a representation of a typical power supply Vcc over time under different conditions. The top waveform 10 corresponds to a normal Vcc value provided by the power supply when there is no load from the IC. When the IC is in operation, the internal voltage is reduced as shown by the lower lines 12, 14. The second or next highest voltage waveform 12 represents an example of dynamic power plane voltages on the IC during functional test. These correspond closely to the voltage under various states of normal operation. As can be seen, there are negative spikes 16 that occur at clock edges. The spikes are not uniform because the voltage will droop more or less depending on the number and loading of transitioning logic cells. In normal operation, different numbers of logic cells are active at different clock edges. The bottom waveform 14 represents power plane voltages during a structural scan test capture phase. During the structural scan test capture phase, on average a much larger percentage of the logic cells are active on every clock pulse, so the negative spikes 18 are much greater and the average voltage is also lower.

The lower waveform shows that the power supply system, from voltage rails to conducting pathways within the IC is stressed more under scan operation, in order to power so much of the IC switching simultaneously. To achieve a correlation between a functional test and a structural scan test, the power profiles must be more closely aligned. This would require the structural scan test power profile to have less offset, and shallower spikes. In other words, the structural scan test waveform 14 must be closer to the level and behavior of the functional test waveform 16.

Embodiments of the present invention provide a means to tune the scan capture phase activity factor to modulate the capture phase Vcc droop. This positively mitigates a major blockage to the structural scan test correlating with normal operational speed functional test. In FIGS. 2 through 6, active logic is indicated by clear or unshaded cloud forms 23. On the other hand, inactive logic is indicated by shaded clouds 24. The inactive logic reduces the amplitude of the Vcc droops. The ratio of active to inactive logic can be characterized by an activity factor. The average reduction in capture phase active logic raises the average at-speed capture phase voltage.

The Vcc droop in the power plane voltages are primarily related to the activity factor of the IC. FIG. 2 is a diagram of two standard scan chains 21, 22. Each scan chain has some active capture phase logic indicated by unshaded or clear clouds 23 and some non active capture phase logic indicated by shaded clouds 24. The boxes 25 along each chain represent flip-flops that are a part of the scan chain. The activity or inactivity of the flip-flops is indicated by the corresponding cloud's shading. Additionally the clouds also symbolize that each flip flop has additional combinatorial cells that it drives.

FIG. 2 represents the execution of a typical functional cycle. As shown in the diagram, only small amounts of logic are active during any given clock cycle. This is depicted with the small number of clear clouds 23. The diagram of FIG. 2 represents activity during a single clock cycle.

In functional tests, the propagation of the functional vectors are specifically designed to exercise specific logic in a specific way. As indicated in FIG. 2 by the shading, only some of the logic along each scan chain is active.

FIG. 3 represents the same logic as in FIG. 2, with the two scan chains 31, 32 representing the activity seen during a typical scan capture phase cycle. In structural scan, it is typical for large amounts of logic to be active during every capture phase clock cycle. This is depicted in FIG. 3 with all unshaded clouds 33. A comparison of FIGS. 2 and 3 shows why the Vcc power plane voltages droop more during a scan capture cycle than during a functional cycle. As described below, these two can be equalized to provide an economical test that can be tuned after an IC design is complete, during the vector generation stage of development.

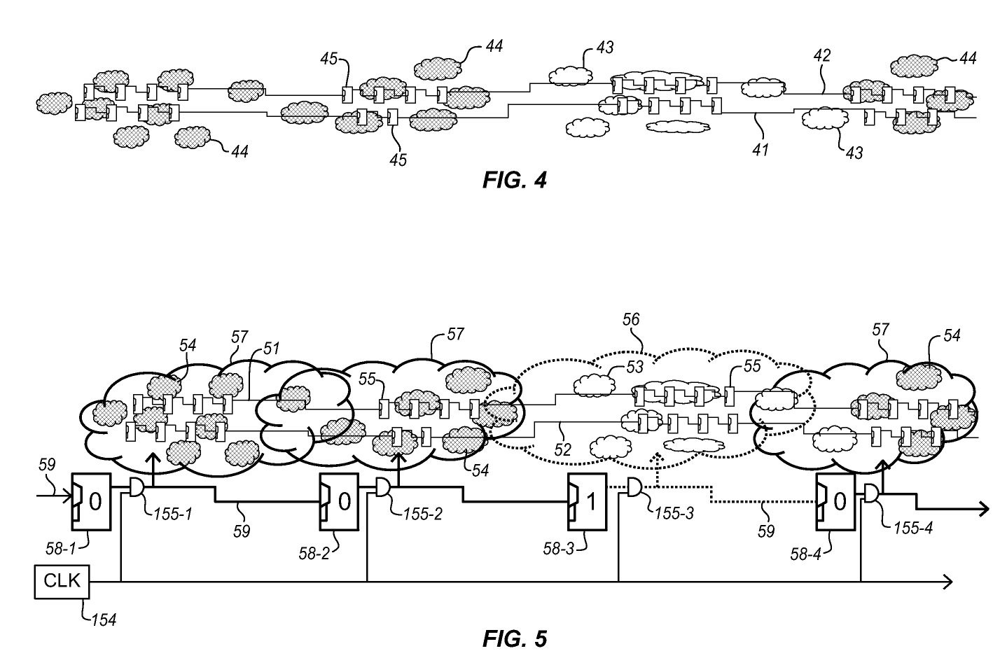

FIG. 4 represents an alternative way of reproducing the scan capture phase activity factor of a specific cycle that is equivalent to that of FIG. 2. The tuning can control how much logic is active in FIG. 4 during any structural scan capture cycle. In this case, FIG. 4 represents this average equivalence by depicting different unshaded or clear clouds than in FIG. 2 but the same total number of clear clouds. In order to build on the example, FIG. 4 shows the same pair of scan chains 41, 42, as those in FIGS. 2 and 3. Each scan chain is made of a sequence of flip-flops 45. Clouds are used again to show active logic with unshaded clouds 44 and inactive logic with shaded clouds 43. FIG. 4 shows an activity factor as indicated by the unshaded clouds that is similar to that of FIG. 2, although the active logic is grouped together in FIG. 4 and not distributed across the scan chain as in FIG. 2.

In embodiments of the present invention, testing is performed only during the capture phase where the chain is not active and the flops are interconnected as they are in functional operation. Performance is not measured during the period when the vectors are input by a shift through the chain only and the flops act as they do in functional operation. In other words, for the tuned scan capture phase described herein, there are no transactions on the chain itself, only on the functionally-used inputs of the flops of the chain.

By controlling the number of active clouds in FIG. 4, the amount of active logic in the FIG. 4 test may be adjusted to more closely correspond to that of any given functional test, e.g. to the number of active clouds in a functional test as in FIG. 2. The FIG. 4 test activates different logic but that does not typically matter in a speed correlation outcome. Over the course of the complete set of scan patterns all the clouds will have times when they are active and the various combinations and permutations of active and inactive clouds will provide the entire cloud coverage. A variety of different techniques and equipment may be used to tune the structural Vcc droop to look more like the functional Vcc droop by tuning the activity factor of a scan test to more closely resemble the activity factor of a functional test.

In order to tune the activity factor and thereby the Vcc droop, the amount of transitioning logic during each scan capture cycle may be controlled. There are different ways to do this. In one example, the clocking sources provided to the flip-flops are clumped into clock regions. This is represented by the big clouds 56, 57 in FIG. 5. Small to medium groups of logic are clocked under independent controls. Localized clock gating can be used to enable and disable clock sources to each group. In the same way leaf (or near-leaf) elements of traditional clock trees may be used in an analogous fashion. These localized clock gates are depicted by the four independent clock inputs to the big clouds 56 and 57 of FIG. 5.

The scan architecture of FIG. 5 again depicts, for illustration purposes, two scan chains 51, 52 although more or fewer may be used. The scan chains connect chains of flip-flops 55 or other logic devices. While the scan lines are shown as straight linear connections, the actual direction and path of the scan lines may include angles and turns and may not be linear. In addition, there may be multiple forks and branches in one or all of the scan lines. The activity during a capture phase cycle is represented by clouds that are either unshaded or clear clouds 53 for an active region of logic or by shaded clouds 54 for an inactive region of logic. As shown, the active clouds 53 are clustered into one group indicated as a big active cloud 56, while the inactive clouds 54 are clustered into three groups indicated as big inactive clouds 57.

Each cloud's clock is controlled by a dedicated clock control enable signal or by a shared control for a specific number of clock gates (not shown). The clock gate override signal is supplied by one or more clock gate override circuits 154 which supply the clock gate override signal into an AND gate 155-1, 155-2, 155-3, 155-4 for each cloud. The depicted AND gate could be an OR gate or a MUX or some more complex logic used to override this clock gate region control mod of the illustrated embodiment. The clock gate override signal is one input into each AND gate. The other input is a clock gate enable/disable 58-1, 58-2, 58-3, 58-4 for each AND gate. Using the AND gates, the clock control gates control whether or not each cloud or clock region receives a clock signal.

As an example if the enable is asserted low then an OR gate may be used to easily force a disable of the mode as a high on the clock gate override signal input. The OR then always sends out a high and that mode may be used for shifting. The clock gating is disabled and allows the clocks through to insure that all flops get a clock during shifting. The clock signal is received regardless of any other enable or disable control of a particular clock region during a scan test capture phase. In other words, the effect of the clock gates is nullified during the shift phase by the clock gate override signal 154.

Clock control signals are applied to each clock gate 58-1, 58-2, 58-3, 58-4, respectively. The scan operation has control of the clock gate controls so that it is able to control the clock gates during the scan capture phase to artificially reduce the number of clock gates that are enabled. This effectively reduces the logic that scan can toggle, reducing the average and instantaneous power consumption on each clock edge. This has the intended effect of raising the average supply voltage and reducing the magnitude of the spikes shown in FIG. 1, item 18. As a result, the applied voltage is made to more closely resemble line 12 of FIG. 1 with voltage droops 16 which more closely resemble normal operation.

In the embodiment shown in FIG. 5, the clock gate controls are chained serially so that each clock gate receives an external clock control value 59 from the gate before it during the scan shift phase. Because the clock gates are arranged as a chain, clock control signals can be supplied to each chain just as any other scan vector. During the capture phase, the clock signal is propagated from each clock gate control element to the corresponding clock gate causing it to allow the clocks through it or to gate them. This has the effect of allowing the scan capture phase activity in the respective clock region to occur or not to occur thus effectively mitigating the overall activity factor.

Depending on the implementation, each big cloud may alternatively be clocked by a respective leaf or branch of a clock tree or using any other clock propagation system. The clouds are shown as clock regions for purposes of the present description. There may be more or fewer clock regions and more or fewer clouds, depending on the particular implementation. There may be a direct correspondence between clouds and clock regions, but the invention is not so limited.

While in this and the other figures a scan chain is shown with a serial sequence of connected clock gates and AND gates, the invention is not so limited. The clocks, the flops, and the logic gates may be arranged in any of a variety of other configurations. The clock gate controls that are connected in a chain as shown in FIG. 5 may be separate and apart from any other clock gates. The IC and its circuits may include other clock controls for power saving, heat management or other purposes.

A separate set of clock gates for scan allows the activity factor to be controlled notwithstanding any functional or management clock controls. Each clock region has a separate clock gate apart from the rest of the scan logic to allow the gate to rotate or hold regardless of the clock region. If no special precaution is implemented then the shift and rotate link may be broken as shifting into a flop that has no clock is the same as dropping the data that should have gone into it. Similarly shifting out from a flop that has no clock is like shifting out a constant cycle after cycle. A special clock is particularly useful for the illustrated embodiment with shift/hold/rotate flops. For other implementations a region clock gating override signal may be used.

As shown, the first 58-1, second 58-2, and fourth 58-4 clock gates are disabled with a 0 or low input and the third clock gate 58-3 is enabled with a 1 or high input. This is provided as an example only and any other polarity of enabled and disabled clock gates may be configured depending on the intended activity factor and the configuration of the system. Other types of logic may be also be used as an alternative to AND gates and connected in a different configuration. As a result, only the third big cloud is active. All of the logic in the first, second and fourth big clouds is inactive with shaded clouds and the all of the logic in the third big cloud is active with unshaded clouds. The all-or-nothing aspect of the clock control is shown in FIG. 5 as an example of how the tuning may be controlled, however, even within the active cloud, there may be some inactive gates due to other control mechanisms.

The result of the clock gate control in the illustrated example is that roughly 25% of the logic is actively clocked and the scan vectors will dictate within that 25% of the clocked logic how much of it is toggling. This is about the same activity factor as in FIGS. 2 and 4. As a result, the load on the power supply rails will be about the same and the Vcc droop of FIG. 1, waveforms 12 and 14, will be about the same. Using the gated clocks, the system can be exposed to a structural scan which may normally have an activity factor close to 50%. However, with clock gates switched off, the actual activity factor is 12.5% simulating the activity factor of a functional test. 12.5%, 25% and 100% are presented only as example to convey the principles of using gated clock signals. In many tests scan is toggling about 50% of the active logic at any one time, although the precise number may be very different depending upon the particular vectors and the circuit configuration. This is referred to herein as a 100% activity factor so that with a 25% activity factor about 12.5% of the active logic will be toggling. These values are presented only as example, the desired activity factor and percent of active logic may be adapted and tuned as described herein to suit a variety of different kinds of tests. The activity factor for normal operation may also vary greatly for different types of IC's and for different intended applications.

While four big clouds are shown in FIG. 5, each with 6-9 active logic areas, this is provided only for explanation purposes. A typical scan chain will have many more than the illustrated 28 logic elements or logic areas and there may be many more than four localized gate clock areas. Each localized clock gate may control tens, hundreds, or thousands of logic elements. The drawing figures are simplified in order to render the principles more clear.

The control of the clocks may be done using a specialized scan chain of clock gating control elements. However the gating elements may be embodied in many ways within a chain format and several ways outside of a chain format. Examples of a chain format include a multi-cycle shift chain, a single cycle shift chain, a standard scan chain intermixing these elements with standard functional scan elements. In embodiments not using a chain, the control data can come in as independent controls that may or may not come from a tester input, an FSM (Finite State Machine), or a set of registers. FIG. 5 shows the clock gates configured as elements of a single or multi-cycle shift chain. The chain 59 interconnects the clock gate control elements so that they can all be controlled using a single input/output port.

The clock gate chain may be used together with normal structural scan capture cycles. This provides a precise amount of control over how many regions are active during any one capture cycle. The precision is limited only by the amount of logic controlled by each gate and the number of regions. Controlling the individual clock gates independently allows the capture phase activity factor to be modulated which allows the resulting Vcc droop of each capture cycle to be fine tuned.

To enhance scan coverage efficiency, the chain of localized clock gates can be embodied as a programmable or controllable latency shift chain or chains. This chain can further be configured to loop back onto itself or even into multiple loops. In addition, each clock gate in the latency shift chain can implement a Hold or Rotate feature on each cycle. The Hold or Rotate feature may be implemented in many ways including but not limited to a simple mux (multiplexer) feedback loop. This chain can further be configured to operate from a pattern generator that can maintain an average activity factor range.

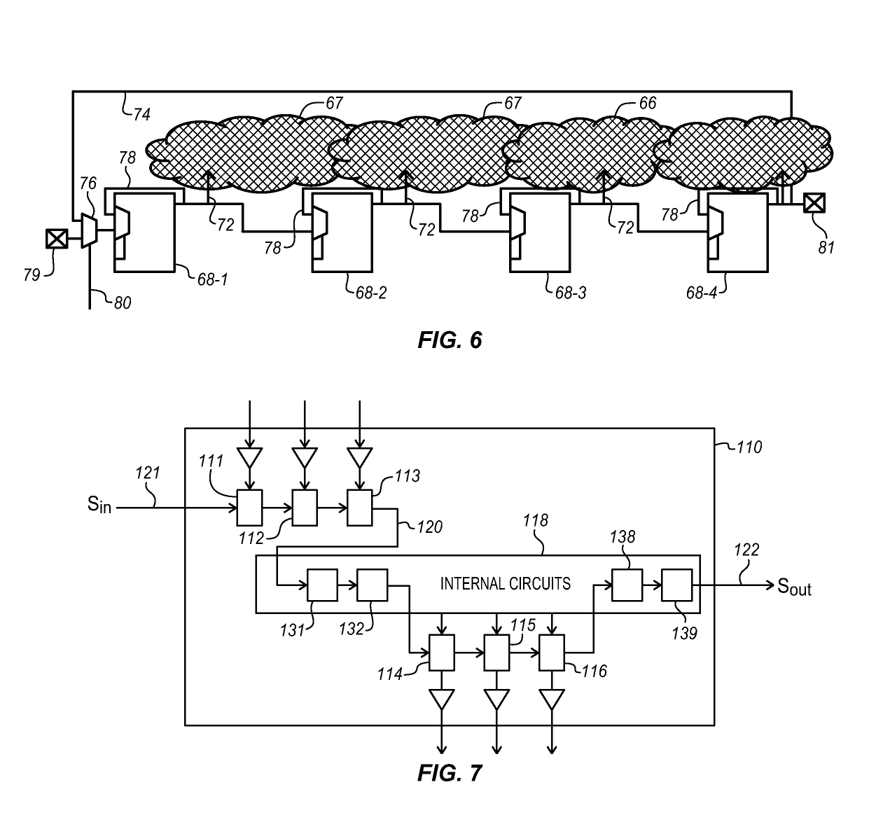

FIG. 6 shows a chain of localized clock gates 68-1, 68-2, 68-3, 68-3 connected together in a chain. As in FIG. 5, the received clock control signal 79 is propagated through each clock gate in series to drive each of the clock regions which are indicated by the big clouds 66, 67. The logic elements are generalized as four big clouds 66, 67 which contain one or more logic elements as in FIG. 5. A clock control override signal is supplied from a clock override source (not shown) as an input 72 to each local group or cluster of logic components as indicated by the big clouds. The clock input is distributed to the logic components in any of a variety of different ways. The output of the last clock gate is shown as an output port 81 which may be provided to other chains.

For illustration purposes, the programmable controllable latency chain is shown as a single feedback loop 74 from the output of the end of the chain back to a mux 76 at the front of the chain. The mux receives the feedback loop and the input clock control 79. The mux output is coupled to the input of the first clock gate 68-1. The configurable latency chain also has a configurable latency shift option line 78 for each clock gate. While a single feedback line and four clock gates in a linear chain are shown, the chain may be much more complicated with many more clock gates and many more connections and branches of connections than are shown.

The configuration of FIG. 6 provides a means to load the latency chains using a shift or rotate function at an enable input 80 to the mux. It also provides a user or automation logic with an ability to select whether the latency chain or chains should be shifted, held, or rotated on each capture cycle. This control enables multiple at-speed captures using the same active logic or different active logic or different combinations of active logic. Changing and selecting the logic that is to be active allows for higher utilization of the standard scan chain shift in the data before performing a shift out of the standard scan chains. At the same time, the capture phase activity factor can be controlled. This has the effect of recovering a significant portion of the loss between clock gate region transition coverages.

This type of localized clock gate chain configuration automatically regains some coverage that may be lost by having some capture logic clock gated. In addition, in the illustrated embodiment, the clock gate chain does this coverage recovery efficiently by using the faster at-speed capture clocks to shift or rotate the clock gate chains during the capture cycles. However, it should be noted that the techniques of local clock gate chain rotation, shifting or holding is not limited to the use of faster at-speed clock cycles nor to performing the rotation, shifting or holding functions in parallel with the capture cycles.

As described above, Vcc droop can be continuously mitigated for typical, single capture and multiple capture Launch Of Capture (LOC) scan vectors. The techniques may even be applied to standard scan vectors derived from standard Scan/Algorithmic Test Pattern Generator (ATPG) tooling. In addition, only a minimal silicon area is added beyond what is needed for traditional scan implementations. The added clock gates and connections do not impact performance paths any more than the components required for standard functional and structural scan. The tuning factors may be changed after the silicon design is completed and the parts are manufactured and do not vary by process temperature and voltage skews. The independence from temperature and voltage skews eliminates the need for any calibration.

Scan tooling and scan methods already in wide use may be used to perform at-speed testing with the added ability to better correlate to in system functional speed. This allows for speed binning with scan. Binning allows the speed of the device to be determined so that the device be classified appropriately. At-speed functional testing-based binning can therefore be avoided saving cost and time.

The techniques and structures described herein may be applied to structural scan, structural ATPG tooling, and other types of structural testing with at-speed correlation to functional scan speed for any flip flop based digital design. A scan capture phase activity factor can be tuned to provide a means for at speed correlation and hence speed binning via scan.

FIG. 7 is a simplified block diagram of a conventional IC device or die 110 incorporating a scan chain 120 including multiple logic elements, flip-flops, or cells 111-116, 131, 132, 138, 139, for scan testing. The scan may be a boundary-type scan, a structural scan or any other type or variation of scan, depending on the particular configuration and design. The scan cells 111-116 are shown wrapped around the internal circuit elements 118 and are disposed between the respective IC inputs and outputs and the internal circuit elements 118. This is appropriate for a boundary scan. For a more generalized scan, more of the scan flops in the IC may be made scannable by adding flops disposed in the internal circuitry 118, such as scan cells 131, 132 and 138, 139. A complete, or 100 percent, scan testing may involve millions of scan cells. The scan chain 120 connects to each of the scan cells that are to be included in the scan. In this example, it is a single serial scan chain with one scan input 121 (Sin) and one scan output 122 (Sout). As mentioned above, the scan cells will be grouped into multiple clock regions (not shown).

A scan chain may be any given number of scan cells stitched or connected together forming a chain with any number, though usually a limited number of inputs and corresponding outputs, e.g. input (Sin) and output (Sout). In the illustrated embodiment, not only boundary-type scan cells 11-16, but also some scan cells resident in the internal circuitry of the device create the scan chain which proceeds from the scan input (Sin) 121 through some boundary scan cells 111, 112, 113 then through internal scan cells 131, 132 out through boundary cells 114, 115, 116 and finally through internal scan cells 138, 139 to and through the scan output (Sout) 22. There may be branching in the scan chain or it may constitute an unbroken continuous connection.

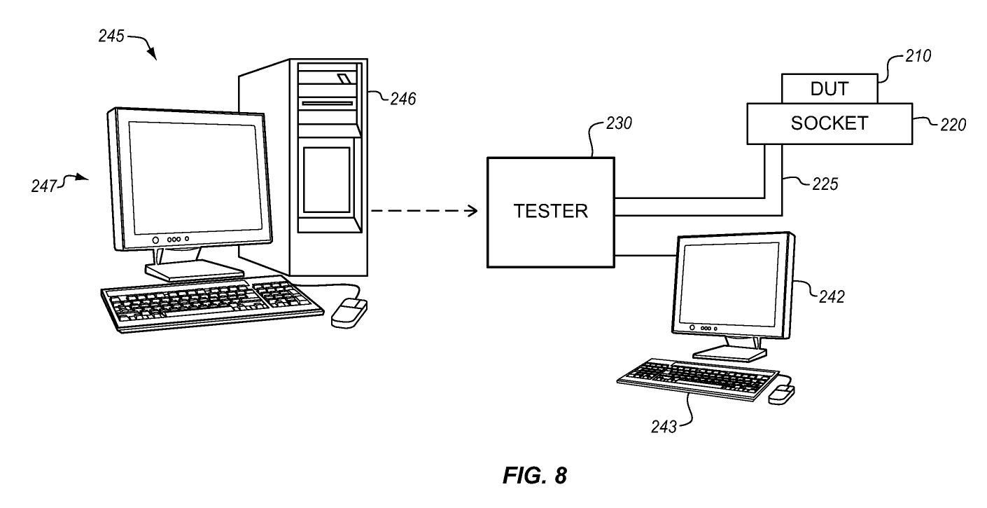

FIG. 8 shows a test configuration for operating the structural, and tuned scans described above. The die that is to be tested or device under test (DUT) 210 is mounted or socketed to a test bed 220, such as a socket or a bed of nails. The test bed is coupled to a test tool 230 through a connecting cable 225. The test tool powers the DUT, provides the scan inputs or scan vectors, and reads the scan output. Some of the functions of the test tool such as power supply or data operands, may alternatively be provided by other connected equipment. While only one test bed 220 is shown, the test tool may simultaneously scan many DUTs at the same time.

In another embodiment, testing as described herein may be performed at the wafer level (not shown). Instead of a socket, a probe card may be used to interface the tester and the DUT within a wafer of DUTs. Other variations of tester to DUT are also not shown but may be used to characterize the DUT.

The test tool such as an ATE tool is connected through an interface to a control console such as a monitor 242, and keyboard and mouse 243. This allows an operator to evaluate and control the operation of the tester. The console includes processing and storage resources and may be based on a conventional computer architecture coupled to specialized tester hardware and interfaces. Using the control console, the user can control the test tool, run scans, review results and configure a variety of tests. The test tool may also have measurement and analysis capabilities to read temperature, power consumption, clock speed and other parameters of the DUT, these may be also be provided to the user at the console. The console may track statistics for each DUT and then provide reports. The console may drive the test tool using storage and processing resources at the console or the console may run autonomously.

The computer control console or another computing device or array may also be operated as a scan tool. A scan tool 245 may be implemented as a general purpose computer 246 with processing and storage resources, and a user interface 247, such as a display, mouse, and keyboard. The scan tool operates off line using e.g. a SCAN Tool software package to analyze a design and develop and insert scan logic into the design of the chip. The scan logic will eventually be used to perform scan testing. Clock scan chains may also be designed and inserted in the same way. The scan tool also determines the scan vectors that best test the device. These can then be transferred to the tester for use in analyzing a DUT as indicated by a dotted line arrow in the figure.

The tester 230 performs the task of injecting the vectors as a set of electrical stimuli into the DUT and comparing the outputs from the device with expected outputs that the scan tool predicted. This stimuli is however, not limited to electrical stimuli. Optical, Radio Frequency (RF), or numerous other forms of input and output signals may be used. If the results match the expected results, then the DUT is passed. As mentioned above, operational speed can also be tested in this way. The scan tool may provide vectors to the computer control console to be provided to the tester or directly to the tester.

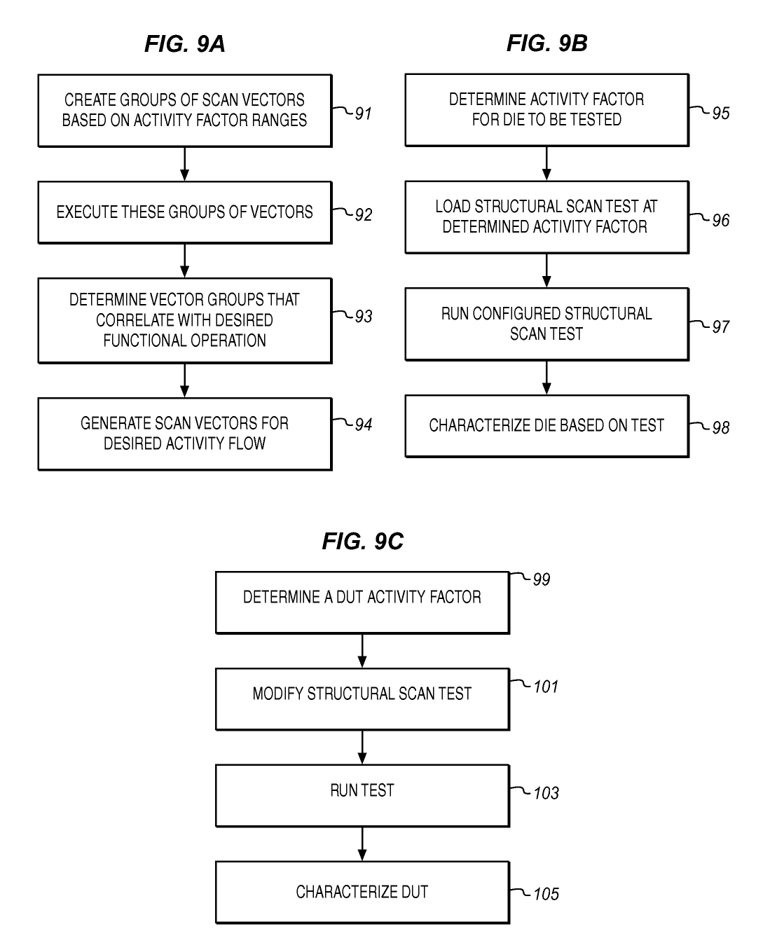

FIG. 9A is a process flow diagram of tuning a structural scan for testing an IC under desired conditions. The process generates groups of scan vectors for use in the testing as described above. Such a process may be performed by a scan tool or by the processing resources of the tester or in other equipment. At 91 groups of scan vectors are created by the scan tools or in any other way. These vectors are grouped based on common activity factor levels. The grouping allows many common activity factor vectors to be executed to easily see how well a correlation is occurring.

At 92 the groups are executed to determine which groups achieve the desired activity factors. This may be done by exposing the die, a similar die, or a standardized die to normal operation and then measuring power consumption by the die in normal operation. This power consumption can then be used as standard for matching the activity factor against. Alternatively, a theoretical design power consumption may be used. Instead of power consumption, the droop in a power supply voltage supplied to the die may be used as the measure for normal operation. As a further alternative, the amount of active logic in the die during normal operation may be determined.

As described above, the activity factors may be based on normal functional operation in different applications and environments. As described above, the voltage droop at the power supply at an internal set of points or external to the DUT may be used to characterize the different activity factors. For a test of normal operation, an activity factor that puts the same stress on the power supply as normal operation may be selected. Alternatively, depending on any guardbanding strategy one of more or less stress may be selected. These selections and execution may also be done using simulations based on theoretical IC characteristics in the design system. At 93, groups of vectors are selected for the desired characteristics.

Having selected the groups of scan vectors that are to used to create the desired activity factor under structural scan at 93, at 94 the volume of scan vectors are generated to match the selection. This volume is the actual vector that will be written into the DUT to prepare the test.

FIG. 9B is a process flow diagram of applying a tuned structural scan for testing an IC at normal operational or at stressed operational speeds. At 95 an activity factor is determined for the die that is to be tested. The activity factor will depend on the particular type of test. Some activity factors may be preferred for maximum stress tests, while other activity factors may be used to emulate normal operation, for example.

At 96, a structural scan test is loaded that is designed to obtain an intended activity factor. In some embodiments, this activity factor will correspond to a desired level of operation such as normal operation. The scan may be configured by the scan tool or an operator based on obtaining a similar power consumption, amount of voltage droop, or number of active logic circuits, or scan cells. For the activity factor, or amount of active logic, selected clock regions, or selected clock distribution branches of a clock distribution tree may be disabled. Alternatively, clock signals to groups of logic circuits may be controlled in another way.

The configuration may be determined with direct calculation or by iteration. For example, some number of clock regions may be disabled, then a scan can be run. The power consumption, voltage droop or another parameter can be monitored. These measured parameters obtained during the scan may be compared to the target values and then more or fewer clock region may be disabled, depending on the comparison. Another test run can be made and another comparison with further adjustments until the desired values are obtained. In this way, the scan tool and the test tool may cooperate or the tester may iterate to find the most effective vectors for the intended tests.

With the parameters and configuration of the scan loaded, at 97, the configured or modified structural scan test capture phase is run. The configured structural scan test capture phase may be run with normal operational power voltage supplied to the die or with some other special environmental conditions. This allows the power consumption and die behavior under normal power conditions to be characterized. For the structural scan, typically at least one capture cycle of the structural scan will be run, however there may be more. The single cycle may include running multiple capture scan vectors.

After the characterization, the modified structural scan has an activity factor similar to that of a functional operation scan. The lower activity factor allows the operation of the die to be characterized at 98 for normal operation based on the scan test. In addition, the configured structural scan test may be tuned to apply stressed conditions that are higher than normal operation but less than the extreme stress of a structural scan. The die can be characterized in a any of a variety of different ways including power consumption, voltage behavior, temperature, and speed of the die, among others. The speed measurements may be used for testing and for speed binning, depending on the particular implementation.

FIG. 9C is a process flow diagram showing further aspects of the invention. At 99, an activity factor of a die or a wafer to be tested (DUT) is determined. At 101, a structural scan test is modified to run with an activity factor based on the determined activity factor. At 103, the modified structural scan test is run, typically in capture phase mode and at 105, the die is characterized based on the test.

These described embodiments allow the scan and test tools to characterize a die effectively. This is especially true with lower activity factors. Without the independent fine control over clock regions, normal tools are not able to generate sufficiently low activity factors. The activity factor can be fine-tuned using the clock gates to get to the desired coverage levels. The tuning may be done by trying some level of activity, then adjusting the clock control gates to adjust it until the desired factor is obtained.

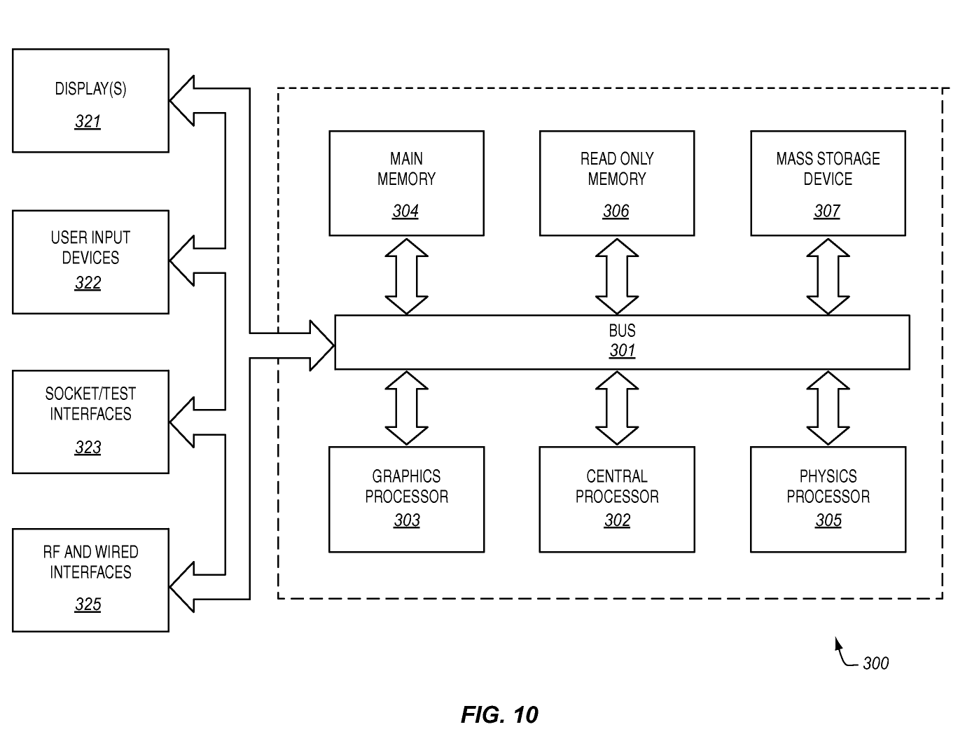

FIG. 10 is a block diagram of a computing system, such as a scan tool, test tool, or workstation suitable for implementing the processes and described above. The computer system may also represent a workstation, personal computer, gaming console, smartphone or portable gaming device suitable for incorporating an IC tested or characterized as described above. The computer system 300 includes a bus or other communication means 301 for communicating information, and a processing means such as a microprocessor 302 coupled with the bus 301 for processing information. The computer system may be augmented with a graphics processor 303 specifically for rendering graphics through parallel pipelines and a physics or math co-processor 305 for calculating physics interactions and IC operation simulations. These processors may be incorporated into the central processor 302 or provided as one or more separate processors.

The computer system 300 further includes a main memory 304, such as a random access memory (RAM) or other dynamic data storage device, coupled to the bus 301 for storing information and instructions to be executed by the processor 302. The main memory also may be used for storing temporary variables or other intermediate information during execution of instructions by the processor. The computer system may also include a nonvolatile memory 306, such as a read only memory (ROM) or other static data storage device coupled to the bus for storing static information and instructions for the processor.

A mass memory 307 such as a magnetic disk, optical disc, or solid state array and its corresponding drive may also be coupled to the bus of the computer system for storing information and instructions. The computer system can also be coupled via the bus to a display device or monitor 321, such as a Liquid Crystal Display (LCD) or Organic Light Emitting Diode (OLED) array, for displaying information to a user. For example, graphical and textual indications of installation status, operations status and other information may be presented to the user on the display device, in addition to the various views and user interactions discussed above.

Typically, user input devices, such as a keyboard with alphanumeric, function and other keys, may be coupled to the bus for communicating information and command selections to the processor. Additional user input devices may include a cursor control input device such as a mouse, a trackball, a trackpad, or cursor direction keys can be coupled to the bus for communicating direction information and command selections to the processor and to control cursor movement on the display 321.

Socket and test tool interfaces 323 are coupled to the bus in the case of test equipment to allow the tester to load vectors into one or more IC's and to receive signals output by the ICs under test.

Communications interfaces 325 are also coupled to the bus 301. The communication interfaces may include a modem, a network interface card, or other well known interface devices, such as those used for coupling to Ethernet, token ring, or other types of physical wired or wireless attachments for purposes of providing a communication link to support a local or wide area network (LAN or WAN), for example. In this manner, the computer system may also be coupled to a number of peripheral devices, other clients. or control surfaces or consoles, or servers via a conventional network infrastructure, including an Intranet or the Internet, for example.

It is to be appreciated that a lesser or more equipped system than the example described above may be preferred for certain implementations. Therefore, the configuration of the exemplary systems 300 will vary from implementation to implementation depending upon numerous factors, such as price constraints, performance requirements, technological improvements, or other circumstances.

Examples of the electronic device or computer system may include without limitation a mobile device, a personal digital assistant, a mobile computing device, a smartphone, a cellular telephone, a handset, a one-way pager, a two-way pager, a messaging device, a computer, a personal computer (PC), a desktop computer, a laptop computer, a notebook computer, a handheld computer, a tablet computer, a server, a server array or server farm, a web server, a network server, an Internet server, a work station, a mini-computer, a main frame computer, a supercomputer, a network appliance, a web appliance, a distributed computing system, multiprocessor systems, processor-based systems, consumer electronics, programmable consumer electronics, television, digital television, set top box, wireless access point, base station, subscriber station, mobile subscriber center, radio network controller, router, hub, gateway, bridge, switch, machine, or combinations thereof.

Embodiments may be implemented as any or a combination of: one or more microchips or integrated circuits interconnected using a parentboard, hardwired logic, software stored by a memory device and executed by a microprocessor, firmware, an application specific integrated circuit (ASIC), and/or a field programmable gate array (FPGA). The term “logic” may include, by way of example, software or hardware and/or combinations of software and hardware.

Embodiments may be provided, for example, as a computer program product which may include one or more machine-readable media having stored thereon machine-executable instructions that, when executed by one or more machines such as a computer, network of computers, or other electronic devices, may result in the one or more machines carrying out operations in accordance with embodiments of the present invention. A machine-readable medium may include, but is not limited to, floppy diskettes, optical disks, CD-ROMs (Compact Disc-Read Only Memories), and magneto-optical disks, ROMs (Read Only Memories), RAMs (Random Access Memories), EPROMs (Erasable Programmable Read Only Memories), EEPROMs (Electrically Erasable Programmable Read Only Memories), magnetic or optical cards, flash memory, or other type of media/machine-readable medium suitable for storing machine-executable instructions.

Moreover, embodiments may be downloaded as a computer program product, wherein the program may be transferred from a remote computer (e.g., a server) to a requesting computer (e.g., a client) by way of one or more data signals embodied in and/or modulated by a carrier wave or other propagation medium via a communication link (e.g., a modem and/or network connection). Accordingly, as used herein, a machine-readable medium may, but is not required to, comprise such a carrier wave.

References to “one embodiment”, “an embodiment”, “example embodiment”, “various embodiments”, etc., indicate that the embodiment(s) of the invention so described may include particular features, structures, or characteristics, but not every embodiment necessarily includes the particular features, structures, or characteristics. Further, some embodiments may have some, all, or none of the features described for other embodiments.

In the following description and claims, the term “coupled” along with its derivatives, may be used. “Coupled” is used to indicate that two or more elements co-operate or interact with each other, but they may or may not have intervening physical or electrical components between them.

As used in the claims, unless otherwise specified the use of the ordinal adjectives “first”, “second”, “third”, etc., to describe a common element, merely indicate that different instances of like elements are being referred to, and are not intended to imply that the elements so described must be in a given sequence, either temporally, spatially, in ranking, or in any other manner.

The following examples pertain to further embodiments. Specifics in the examples may be used anywhere in one or more embodiments. In one embodiment, a method comprises determining an activity factor of a die to be tested, modifying a structural scan test to run with an activity factor based on the determined activity factor, running the modified structural scan test, and characterizing the die based on the test.

In further embodiments, determining the activity factor comprises measuring power consumption by the die in normal operation and wherein configuring the structural scan test comprises configuring the structural scan test to have a similar amount of power consumption.

In further embodiments determining the activity factor comprises measuring droop in a power supply voltage supplied to the die and wherein configuring the structural scan test comprises configuring the structural scan test to have a similar amount of power supply voltage droop.

In further embodiments determining the activity factor comprises determining an amount of active logic in the die during normal operation.

In further embodiments configuring the structural scan test comprises limiting the active logic to an amount similar to the determined amount of active logic.

In further embodiments limiting the active logic comprises disabling selected clock regions of the die.

In further embodiments limiting the active logic comprises disabling selected branches of clock distribution trees of the die.

In further embodiments limiting the active logic comprises controlling clock signals to logic circuit groups of the die by loading a vector into a scan chain that includes control gates for clocks that generate the clock signals.

In further embodiments the scan chain is a chain of clock control gates.

In further embodiments running the configured structural scan test comprises running at least one capture cycle of a structural scan.

In further embodiments running the configured structural scan test comprises running multiple capture scan vectors.

In further embodiments characterizing the die comprises determining a structural speed of the die.

In further embodiments characterizing the die comprises speed binning.

In some embodiments, an integrated circuit comprises a plurality of logic circuits, the logic circuits grouped into clock regions, a plurality of clocks to drive the logic circuits of each clock region, a plurality of control gates, each control gate being coupled to one of the plurality of clocks, the control gates to alternately enable and disable a respective clock to which it is coupled, and a scan chain coupled to each control gate to receive vectors through a scan input to set the state of each control gate.

In further embodiments each control gate is set independent of the operation of any functional logic of the integrated circuit.

In further embodiments each control gate include a hold state and a rotate state.

In further embodiments a machine-readable medium has instructions thereon that when executed by the machine cause the machine to perform operations that comprise determining an activity factor for normal operation of a die to be tested, loading a sequence of scan vectors into the die for a structural scan test, disabling clock regions of the die to lower the activity factor of the structural scan test by an amount based on the determined activity factor, running the structural scan test in a capture phase with the disabled clock regions, and receiving test results from the die based on the structural scan test.

Further embodiments include characterizing the die based on the received test results.

In further embodiments disabling clock regions comprise writing a scan vector into a scan chain that includes clock control gates.

In further embodiments loading a sequence of scan vectors includes writing a scan vector into a scan chain that includes clock control gates.

What is claimed is:

1. A method comprising:
determining an activity factor of a die to be tested;
modifying a structural scan test to run with an activity factor based on the determined activity factor;
running the modified structural scan test; and
characterizing the die based on the test.

2. The method of claim 1, wherein determining the activity factor comprises measuring power consumption by the die in normal operation and wherein configuring the structural scan test comprises configuring the structural scan test to have a similar amount of power consumption.

3. The method of claim 1, wherein determining the activity factor comprises measuring droop in a power supply voltage supplied to the die and wherein configuring the structural scan test comprises configuring the structural scan test to have a similar amount of power supply voltage droop.

4. The method of claim 1, wherein determining the activity factor comprises determining an amount of active logic in the die during normal operation.

5. The method of claim 4, wherein configuring the structural scan test comprises limiting the active logic to an amount similar to the determined amount of active logic.

6. The method of claim 5, wherein limiting the active logic comprises disabling selected clock regions of the die.

7. The method of claim 5, wherein limiting the active logic comprises disabling selected branches of clock distribution trees of the die.

8. The method of claim 5, wherein limiting the active logic comprises controlling clock signals to logic circuit groups of the die by loading a vector into a scan chain that includes control gates for clocks that generate the clock signals.

9. The method of claim 8, wherein the scan chain is a chain of clock control gates.

10. The method of claim 1, wherein running the configured structural scan test comprises running at least one capture cycle of a structural scan.

11. The method of claim 1, wherein running the configured structural scan test comprises running multiple capture scan vectors.

12. The method of claim 1, wherein characterizing the die comprises determining a structural speed of the die.

13. The method of claim 1, wherein characterizing the die comprises speed binning.

14. An integrated circuit comprising:
a plurality of logic circuits, the logic circuits grouped into clock regions;
a plurality of clocks to drive the logic circuits of each clock region;
a plurality of control gates, each control gate being coupled to one of the plurality of clocks, the control gates to alternately enable and disable a respective clock to which it is coupled; and
a scan chain coupled to each control gate to receive vectors through a scan input to set the state of each control gate.

15. The integrated circuit of claim 14, wherein each control gate is set independent of the operation of any functional logic of the integrated circuit.

16. The integrated circuit of claim 14, wherein each control gate include a hold state and a rotate state.

17. A machine-readable medium having instructions thereon that when executed by the machine cause the machine to perform operations comprising:
determining an activity factor for normal operation of a die to be tested;
loading a sequence of scan vectors into the die for a structural scan test;
disabling clock regions of the die to lower the activity factor of the structural scan test by an amount based on the determined activity factor;
running the structural scan test in a capture phase with the disabled clock regions; and
receiving test results from the die based on the structural scan test.

18. The medium of claim 17, further comprising characterizing the die based on the received test results.

19. The medium of claim 17, wherein disabling clock regions comprise writing a scan vector into a scan chain that includes clock control gates.

20. The medium of claim 19, wherein loading a sequence of scan vectors includes writing a scan vector into a scan chain that includes clock control gates.
